(19) United States
(12) Patent Application Publication
(10) Pub. No.: US 2025/0113549 A1
(43) Pub. Date: Apr. 3, 2025

(54) NANOSHEET TRANSISTORS WITH MULTI-LAYERED CHANNEL STRUCTURES

(71) Applicant: International Business Machines Corporation, Armonk, NY (US)

(72) Inventors: Huimei Zhou, Albany, NY (US); Shogo Mochizuki, Mechanicville, NY (US); Effendi Leobandung, Stormville, NY (US); Miaomiao Wang, Albany, NY (US)

(21) Appl. No.: 18/480,143

(22) Filed: Oct. 3, 2023

(51) Int. Cl. H01L 29/786; H01L 29/06; H01L 29/423; H01L 29/66; H01L 29/775

(52) U.S. Cl. CPC H10D 30/6757; H10D 30/014; H10D 30/43; H10D 30/6735; H10D 62/121; H10D 64/017

(57) ABSTRACT

A semiconductor device comprises a stacked structure comprising a plurality of gate structures alternately stacked with a plurality of channel structures. Respective ones of the plurality of channel structures comprise a plurality of stacked semiconductor layers. At least two of the plurality of stacked semiconductor layers in the respective ones of the plurality of channel structures comprise different materials from each other.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming nanosheet transistors with multi-layered channel structures.

In one embodiment, a semiconductor device comprises a stacked structure comprising a plurality of gate structures alternately stacked with a plurality of channel structures. Respective ones of the plurality of channel structures comprise a plurality of stacked semiconductor layers. At least two of the plurality of stacked semiconductor layers in the respective ones of the plurality of channel structures comprise different materials from each other.

In another embodiment, a semiconductor device comprises a nanosheet structure comprising a plurality of gate structures, and a plurality of channel structures alternately stacked with the plurality of gate structures. Respective ones of the plurality of channel structures comprise a second semiconductor layer stacked between a first semiconductor layer and a third semiconductor layer. The first and third semiconductor layers comprise a first semiconductor material and the second semiconductor layer comprises a second semiconductor material different from the first semiconductor material.

In another embodiment, a semiconductor device comprises a nanosheet transistor comprising a plurality of channel structures in a stacked configuration with a plurality of gate structures. Each channel structure of the plurality of channel structures comprises a middle semiconductor layer disposed between two outer semiconductor layers. The two outer semiconductor layers comprise a different semiconductor material than a semiconductor material of the middle semiconductor layer.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure illustrating semiconductor nanosheet layers, according to an embodiment of the invention.

FIG. 2 depicts a cross-sectional view of a semiconductor structure following dummy gate, gate spacer, inner spacer, bottom isolation layer and buffer semiconductor layer formation, and patterning of semiconductor nanosheet layers, according to an embodiment of the invention.

FIG. 3 depicts a cross-sectional view of a semiconductor structure following growth of an epitaxial source/drain region and inter-layer dielectric (ILD) layer formation, according to an embodiment of the invention.

FIG. 4 depicts a cross-sectional view of a semiconductor structure following dummy gate removal and removal of first sacrificial semiconductor layers, according to an embodiment of the invention.

FIG. 5 depicts a cross-sectional view of a semiconductor structure following removal of second sacrificial semiconductor layers, according to an embodiment of the invention.

FIG. 6 depicts a cross-sectional view of a semiconductor structure following epitaxial growth of channel structure layers, according to an embodiment of the invention.

FIG. 7 depicts a cross-sectional view of a semiconductor structure following replacement metal gate (RMG) formation, additional ILD layer formation and source/drain contact formation, according to an embodiment of the invention.

### DETAILED DESCRIPTION

Illustrative embodiments of the invention may be described herein in the context of illustrative methods for forming nanosheet transistors with multi-layered channel structures, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

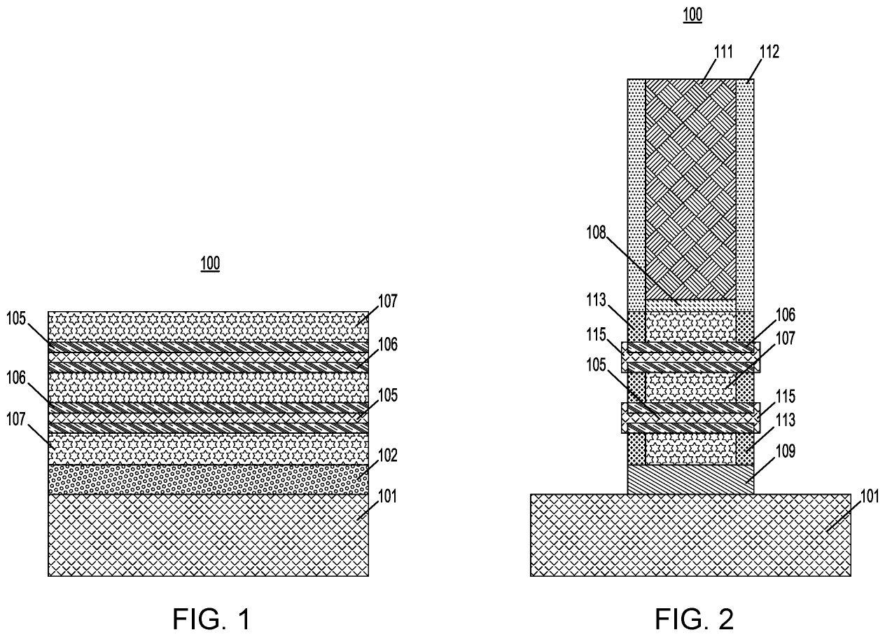

Referring to FIG. 1, a semiconductor structure 100 includes a stacked structure of middle channel structure layers 105, first sacrificial layers 106 and second sacrificial layers 107. In an illustrative embodiment, middle channel structure layers 105 comprise silicon, the first sacrificial layers 106 comprise silicon germanium (SiGe) and the second sacrificial layers 107 comprise SiGe. In illustrative embodiments, the first sacrificial layers 106 comprise a germanium concentration of about 10% (e.g., SiGe10) and the second sacrificial layers 107 comprise a germanium concentration of about 35% (e.g., SiGe35), but the embodiments are not necessarily limited to SiGe10 and SiGe35 for the first and second sacrificial layers 106 and 107. The lowermost second sacrificial layer 107 is formed on an additional sacrificial layer 102 including, for example, SiGe with a different concentration of germanium than that of the first and second sacrificial layers 106 and 107. For example, the additional sacrificial layer 102 has, but is not necessarily limited to, a germanium concentration of about 50% (e.g., SiGe50). As explained in more detail herein, the additional sacrificial layer 102 has a different concentration of germanium than the first and second sacrificial layers 106 and 107 (e.g., higher germanium concentration) so that the additional sacrificial layer 102 can be selectively etched and removed with respect to the first and second sacrificial layers 106 and 107 when forming a bottom isolation layer (see, e.g., FIG. 2 including bottom isolation layer 109). Also, the second sacrificial layers 107 have a different concentration of germanium than the first sacrificial layers 106 (e.g., higher germanium concentration) so that the second sacrificial layers 107 can be selectively etched and removed with respect to the first sacrificial layers 106 (see, e.g., FIG. 4).

A semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101. The semiconductor substrate 101 may also be referred herein to as a semiconductor layer.

The middle channel structure layers 105, first sacrificial layers 106 and second sacrificial layers 107 are epitaxially grown in an alternating and stacked configuration on the additional sacrificial layer 102. A lowermost second sacrificial layer 107 is followed by a first combination of a first one of the first sacrificial layers 106, a middle channel structure layer 105 stacked on the first one of the first sacrificial layers 106 and a second one of the first sacrificial layers 106 stacked on the middle channel structure layer 105. A next second sacrificial layer 107 is stacked on the first combination, followed by a second combination of a first one of the first sacrificial layers 106, a middle channel structure layer 105 stacked on the first one of the first sacrificial layers 106 and a second one of the first sacrificial layers 106 stacked on the middle channel structure layer 105. An uppermost second sacrificial layer 107 is stacked on the second combination. As can be understood, the middle channel structure layers 105 and the first and second sacrificial layers 106 and 107 are epitaxially grown from their corresponding underlying semiconductor layers.

While two combinations of middle channel structure layers 105 and first sacrificial layers 106, and three second sacrificial layers 107 are shown, the embodiments of the present invention are not necessarily limited to the shown number of combinations and second sacrificial layers 107, and there may be more or less layers in the same alternating configuration depending on design constraints. As described further herein, the first sacrificial layers 106 are eventually removed and replaced by outer channel structure layers 116 (FIG. 6), and the second sacrificial layers 107 are eventually removed and replaced by gate structures.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height (e.g., vertical thickness in the cross-sectional views) of the middle channel structure layers 105 and the first sacrificial layers 106 can be in the range of about 1 nm to about 7 nm depending on the application of the device. Also, in a non-limiting illustrative embodiment, a height (e.g., vertical thickness in the cross-sectional views) of the second sacrificial layers 107 can be in the range of about 3 nm to about 10 nm depending on the desired process and application. In accordance with an embodiment of the present invention, each of the second sacrificial layers 107 has the same or substantially the same composition and size as each other, each of the first sacrificial layers 106 has the same or substantially the same composition and size as each other, and each of the middle channel structure layers 105 has the same or substantially the same composition and size as each other.

Although not shown, portions of the nanosheet stacks comprising the middle channel structure layers 105, the first sacrificial layers 106 and the second sacrificial layers 107 are removed, portions of the additional sacrificial layer 102 are removed and portions of the semiconductor substrate 101 are recessed. Isolation regions (e.g., shallow trench isolation (STI) regions) are formed between the remaining nanosheet stacks, and remaining portions of the additional sacrificial layer 102 and the semiconductor substrate 101. The dielectric material of the isolation regions may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Referring to FIG. 2, a dielectric layer 108 and a dummy gate portion 111 are formed on the uppermost second sacrificial layer 107. Although not shown in the cross-sectional view, the dummy gate portion 111 is formed around the stacked nanosheet configuration of the middle channel structure layers 105, the first sacrificial layers 106 and the second sacrificial layers 107. The dielectric layer 108 includes, but is not necessarily limited to, silicon oxide (SiOₓ) (where x is for example, 2, 1.99 or 2.01), silicon oxycarbide (SiOC), SiN, SION, SiCN, BN, SiBCN, SiOCN or some other dielectric. The dummy gate portion 111 includes, but is not necessarily limited to, an amorphous silicon (a-Si) layer. The dielectric layer 108 and the dummy gate portion 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer.

Although not shown, a hardmask layer is formed on the dummy gate portion 111, and exposed portions of the dummy gate portion 111 and dielectric layer 108 not under the hardmask layer are removed to leave remaining parts of the dummy gate portion 111 and dielectric layer 108 as shown in FIG. 2. Gate spacers 112 are formed on sides of the dummy gate portion 111 by one or more of the deposition techniques noted in connection with deposition of the dummy gate material. The spacer material can comprise for example, one or more dielectrics, including, but not necessarily limited to, SiN, SION, SiOC, SiCN, BN, SiBN, SiBCN, SiOCN, SiOₓ, and combinations thereof. The gate spacers 112 can be formed by any suitable techniques such as deposition followed by directional etching. Deposition may include but is not limited to, ALD or CVD. Directional etching may include but is not limited to, reactive ion etching (RIE).

The additional sacrificial layer 102 between the lowermost second sacrificial layer 107 and semiconductor substrate 101 is removed using, for example, an aqueous solution containing hydrogen peroxide (H₂O₂) or a gas containing hydrogen fluoride (HF) to selectively etch the additional sacrificial layer 102 with respect to the semiconductor substrate 101, the middle channel structure layers 105, the first sacrificial layers 106 and the second sacrificial layers 107. The selective etching removes the additional sacrificial layer 102 to form a vacant area where the bottom isolation layer 109 is formed.

Dielectric material is deposited in place of the additional sacrificial layer 102 using deposition techniques such as, for example, CVD, PECVD, RFCVD, PVD, ALD, MBD, PLD, and/or LSMCD, followed by an etch back to form the bottom isolation layer 109 on the semiconductor substrate 101 in place of the additional sacrificial layer 102. The bottom isolation layer 109 may comprise, for example, SiOₓ, SiOC, SiN, SiON, SiCN, BN, SiBCN, SiOCN or some other dielectric. The bottom isolation layer 109 is under a bottom surface of the lowermost second sacrificial layer 107.

Exposed portions of the stacked middle channel structure layers 105, first sacrificial layers 106, second sacrificial layers 107 and bottom isolation layer 109, which are not under the gate spacers 112, dummy gate portion 111 and dielectric layer 108, are removed using, for example, an etching process, such as RIE, where the gate spacers 112, dummy gate portion 111 and dielectric layer 108 are used as a mask. The portions of the stacked structures of middle channel structure layers 105, first sacrificial layers 106, second sacrificial layers 107 and bottom isolation layer 109 under the gate spacers 112, under the dummy gate portion 111 and under the dielectric layer 108 remain after the etching process, and portions of the middle channel structure layers 105, first sacrificial layers 106, second sacrificial layers 107 and bottom isolation layer 109 in areas that correspond to where source/drain regions will be formed are removed. The process for removal of the exposed portions of the stacked middle channel structure layers 105, first sacrificial layers 106 and second sacrificial layers 107 includes, for example, CF₄ gas to selectively remove SiGe and an RIE process with H₂/CF₄ plasma to remove silicon. The process for removal of the exposed portions of the bottom isolation layer 109 includes, for example, CF₄/H₂, CF₄/O₂/N₂, SF₆/O₂/N₂. SF/CH₄/N₂ and/or SF₆/CH₄/N₂/O₂.

Due to, for example, the concentration of germanium in the second sacrificial layers 107, lateral etching of the second sacrificial layers 107 can be performed selective to the first sacrificial layers 106 and to the middle channel structure layers 105, such that the side portions of the second sacrificial layers 107 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portion 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

Following formation of the inner spacers 113, buffer semiconductor layers 115 are epitaxially grown from exposed end portions of the middle channel structure layers 105 and the first sacrificial layers 106. Epitaxial growth is controlled so that the buffer semiconductor layers 115 are formed on the exposed side surfaces of the middle channel structure layers 105 and the first sacrificial layers 106. The buffer semiconductor layers 115 are grown to a thickness (e.g., horizontal thickness in the cross-sectional view) of about 0.5 nm to about 4 nm. In an illustrative embodiment, the buffer semiconductor layers 115 comprise the same material (e.g., silicon) of the middle channel structure layers 105.

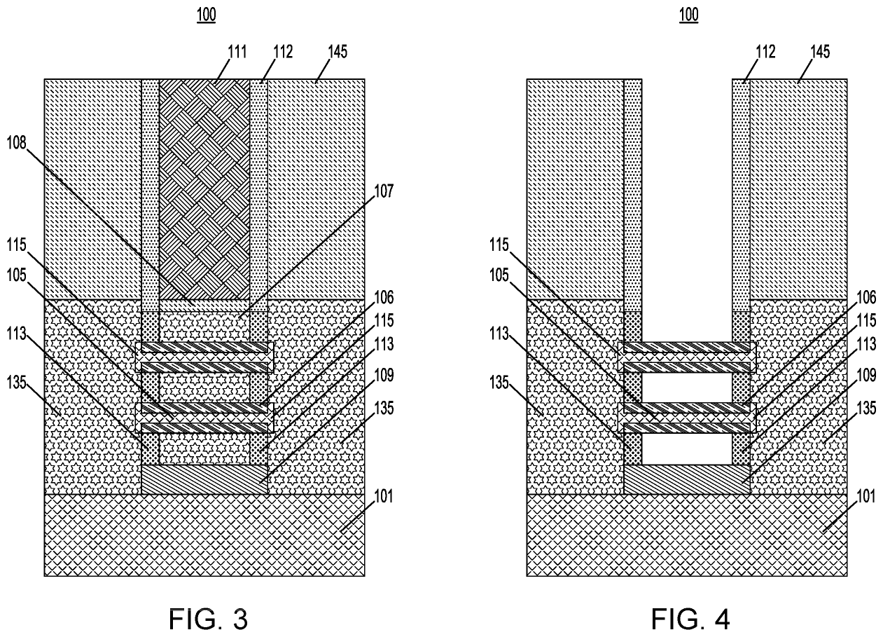

Referring to FIG. 3, epitaxial source/drain regions 135 are grown from the exposed portions of the semiconductor substrate 101 and from the buffer semiconductor layers 115. Side surfaces of the inner spacers 113, which are coplanar with the side surfaces of the first sacrificial layers 106 and the middle channel structure layers 105, contact side surfaces of epitaxial source/drain regions 135. The buffer semiconductor layers 115 are disposed between portions of the epitaxial source/drain regions 135 and the side surfaces of the first sacrificial layers 106 and the middle channel structure layers 105. The top surfaces of the epitaxial source/drain regions 135 are above the top surface of the uppermost second sacrificial layer 107 and dielectric layer 108.

According to a non-limiting embodiment of the present invention, the conditions of the epitaxial growth process for the epitaxial source/drain regions 135 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr—about 300 Torr. In the case of n-type FETS (nFETs), the epitaxial source/drain regions 135 can comprise silicon doped with n-type dopants including, for example, phosphorus (P), arsenic (As) and antimony (Sb). In the case of p-type FETS (pFETs), the epitaxial source/drain regions 135 can comprise silicon doped with p-type dopants including, for example, boron (B), boron fluoride (BF₂), gallium (Ga), indium (In), and thallium (TI).

Inter-layer dielectric (ILD) layer 145 is deposited on the semiconductor structure 100 to fill in portions on and around the epitaxial source/drain regions 135, and on and around the dummy gate portion 111. The ILD layer 145 is deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 145 deposited on top of the gate spacers 112 and dummy gate portion 111. The ILD layer 145 may comprise, for example, SiOₓ, SiOC, SiOCN or some other dielectric.

Referring to FIG. 4, the dummy gate portion 111 and the dielectric layer 108 are selectively removed to create a vacant area where a gate structure will be formed in place of the dummy gate portion 111 and dielectric layer 108. The selective removal can be performed using, for example, hot ammonia to remove a-Si. In addition, the second sacrificial layers 107 are selectively removed to create vacant areas where gate structures will be formed in place of the second sacrificial layers 107. The second sacrificial layers 107 are selectively removed with respect to the first sacrificial layers 106 and the middle channel structure layers 105. The selective removal can be performed using, for example, a dry HCl etch.

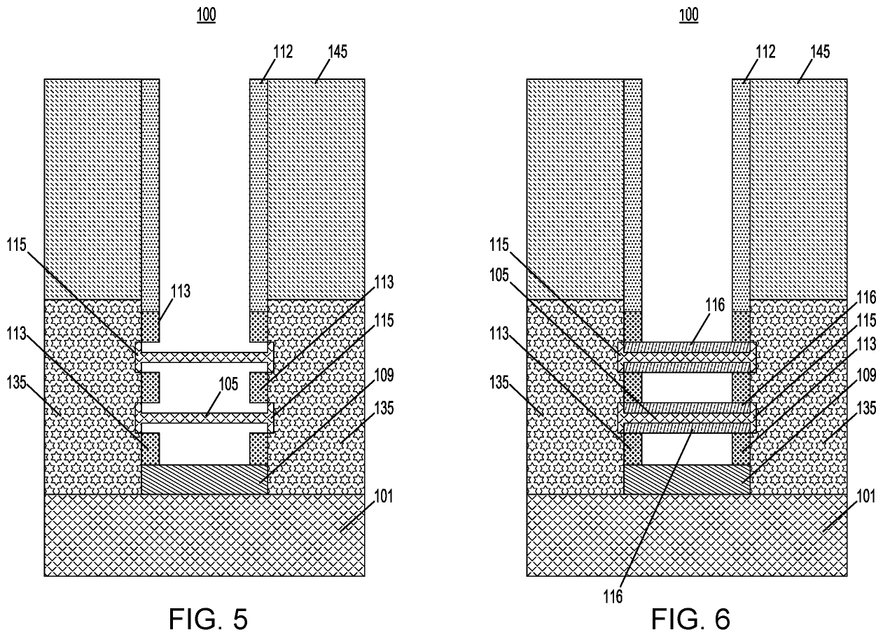

Referring to FIG. 5, the first sacrificial layers 106 are selectively removed with respect to the middle channel structure layers 105 and buffer semiconductor layers 115 to create additional vacant areas over and under top and bottom surfaces of the middle channel structure layers 105. The selective removal can be performed using, for example, an RIE process with vapor phase HCl, remote plasma, etc.

Referring to FIG. 6, outer channel structure layers 116 are epitaxially grown from the middle channel structure layers 105 and from exposed portions of the buffer semiconductor layers 115. Epitaxial growth is controlled so that the outer channel structure layers 116 fill-in the vacant areas left by the removal of the first sacrificial layers 106. In an illustrative embodiment, the outer channel structure layers 116 comprise the SiGe with a germanium concentration of about 40% or greater than 40%.

The combinations of a first outer channel structure layer 116, a middle channel structure layer 105 stacked on the first outer channel structure layer 116 and a second outer channel structure layer 116 stacked on the middle channel structure layer 105 form respective ones of a plurality of channel structures (e.g., two channel structures in this case). As can be understood, outer channel structure layers 116 comprise the same material as each other (e.g., SiGe40 or SiGe with a concentration of germanium greater than 40%). The middle channel structure layer 105 comprises a material different from that of the outer channel structure layers 116 (e.g., silicon).

End portions of the middle channel structure layer 105 and of the outer channel structure layers 116 are disposed between pairs of inner spacers 113 disposed over and under the end portions of the middle channel structure layer 105 and of the outer channel structure layers 116. Each of the buffer semiconductor layers 115 are respectively disposed on respective sides of the respective ones of the plurality of channel structures. In more detail, respective ones of the buffer semiconductor layers 115 are disposed on side surfaces of a corresponding middle channel structure layer 105 and corresponding outer channel structure layers 116. The buffer semiconductor layers 115 are disposed between the respective sides of the respective ones of the plurality of channel structures and one of the plurality of epitaxial source/drain regions 135.

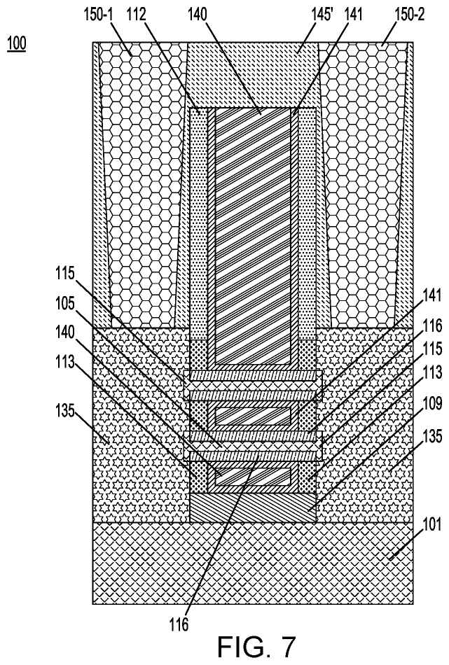

Referring to FIG. 7, gate structures comprising gate regions 140 and gate dielectric layers 141 are formed in the vacant portions left by removal of the dummy gate portions 111 and the second sacrificial layers 107. In illustrative embodiments, each gate dielectric layer 141 comprises, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂Os (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, each gate region 140 comprises a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAIN), titanium aluminum carbon nitride (TiAICN), titanium aluminum carbide (TiAIC), tantalum aluminum carbide (TaAIC), tantalum aluminum carbon nitride (TaAICN) or lanthanum (La) doped TiN, TaN, which can be deposited on the gate dielectric layer. Each gate region 140 can also further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for each gate region 140 as desired. The inner spacers 113 are disposed on sides of the gate structures over and/or under the respective ones of the end portions of a middle channel structure layer 105 and of the outer channel structure layers 116 of a channel structure.

In the semiconductor structure 100, the gate dielectric layers 141 of the respective ones of the plurality of gate structures contact at least one outer channel structure layer 116. The gate dielectric layers 141 of the respective ones of the plurality of gate structures, which are disposed around the gate regions 140 contact a top surface and/or a bottom surface of one or more adjacent outer channel structure layers 116.

An additional ILD layer 145′ is deposited on the uppermost gate structure. The ILD layer 145′ comprises the same or similar material and is deposited using the same or similar deposition techniques as used for the ILD layer 145, followed by a planarization process, such as, CMP. Source/drain contacts 150-1 and 150-2 (collectively “source/drain contacts 150) are formed in the ILD layers 145 and 145′. The source/drain contacts 150 contact the epitaxial source/drain regions 135 formed on opposite sides of the stacked nanosheet structure comprising the plurality of channel structures alternately stacked with the plurality of gate structures. In forming the source/drain contacts 150, openings are formed through portions of the ILD layers 145 and 145′. The openings expose portions of the epitaxial source/drain regions 135 on which the source/drain contacts 150 are to be formed. According to an embodiment, masks are formed on parts of the ILD layers 145 and 145′, and exposed portions of the ILD layers 145 and 145′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the source/drain contacts 150. The metal layers comprise, for example, a silicide layer, such as Ni, Ti, NiPt, etc., a metal adhesion layer, such as TiN, and a conductive metal fill layer, such as W. Al, Co, Ru, etc., and can be deposited using, for example, a deposition technique such as CVD, PECVD, RFCVD, PVD, ALD, MBD. PLD, LSMCD, sputtering and/or plating, followed by a planarization process such as, CMP to remove excess portions of the metal layers from on top of the ILD layer 145′. The source/drain contacts 150 extend through the ILD layers 145 and 145′ to land on and contact the corresponding epitaxial source/drain region 135.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming nanosheet transistors with multi-layered channel structures. With conventional approaches, channel regions have non-uniform shapes with smaller thicknesses at central portions than at end portions (e.g., bone shapes), resulting in low epitaxial source/drain region quality. The embodiments advantageously provide uniform nanosheet channel structures with a configuration where a silicon layer is sandwiched between two relatively high percentage SiGe layers (e.g., SiGe40 or greater than 40% germanium). As noted herein above, the end portions of the sandwich structure are disposed between inner spacers 113 which are adjacent the gate structures.

Illustrative embodiments advantageously provide uniform junctions along channel regions, where the junctions from the channel structures to the epitaxial source/drain regions 136 over and under the inner spacers 113 are formed by a combination of removal of first sacrificial layers 106 (e.g., SiGe10) and subsequent growth of outer channel structure layers 116 (e.g., SiGe40 or greater than 40% germanium).

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a stacked structure comprising a plurality of gate structures alternately stacked with a plurality of channel structures;
wherein respective ones of the plurality of channel structures comprise a plurality of stacked semiconductor layers; and
wherein at least two of the plurality of stacked semiconductor layers in the respective ones of the plurality of channel structures comprise different materials from each other.

2. The semiconductor device of claim 1, wherein the plurality of stacked semiconductor layers in the respective ones of the plurality of channel structures comprise a first semiconductor layer, a second semiconductor layer stacked on the first semiconductor layer and a third semiconductor layer stacked on the second semiconductor layer.

3. The semiconductor device of claim 2, wherein the first semiconductor layer comprises a same material as the third semiconductor layer.

4. The semiconductor device of claim 3, wherein the second semiconductor layer comprises a different material from the first and third semiconductor layers.

5. The semiconductor device of claim 4, wherein:
the first and third semiconductor layers comprise silicon germanium; and
the second semiconductor layer comprises silicon.

6. The semiconductor device of claim 2, wherein parts of the first, second and third semiconductor layers are disposed between a plurality of spacers, wherein respective ones of the plurality of spacers are disposed adjacent respective ones of the plurality of gate structures.

7. The semiconductor device of claim 2, further comprising a plurality of additional semiconductor layers respectively disposed on respective sides of the respective ones of the plurality of channel structures, wherein respective ones of the plurality of additional semiconductor layers are disposed on side surfaces of the first, second and third semiconductor layers.

8. The semiconductor device of claim 7, further comprising a plurality of source/drain regions respectively disposed on opposite sides of the stacked structure, wherein the plurality of additional semiconductor layers are disposed between the respective sides of the respective ones of the plurality of channel structures and one of the plurality of source/drain regions.

9. The semiconductor device of claim 7, wherein the plurality of additional semiconductor layers comprise a same material as the second semiconductor layer.

10. A semiconductor device comprising:
a nanosheet structure comprising:
a plurality of gate structures; and
a plurality of channel structures alternately stacked with the plurality of gate structures;
wherein respective ones of the plurality of channel structures comprise a second semiconductor layer stacked between a first semiconductor layer and a third semiconductor layer; and
wherein the first and third semiconductor layers comprise a first semiconductor material and the second semiconductor layer comprises a second semiconductor material different from the first semiconductor material.

11. The semiconductor device of claim 10, wherein:
the first semiconductor material comprises silicon germanium; and
the second semiconductor material comprises silicon.

12. The semiconductor device of claim 10, wherein:
the nanosheet structure further comprises a plurality of spacers disposed on sides of the plurality of gate structures; and
parts of the first, second and third semiconductor layers are disposed between two of the plurality of spacers.

13. The semiconductor device of claim 10, wherein the nanosheet structure further comprises a plurality of spacers disposed on sides of the plurality of gate structures at least one of over and under portions of the respective ones of the plurality of channel structures.

14. The semiconductor device of claim 13, wherein sides of respective ones of the plurality of spacers are coplanar with sides of the respective ones of the plurality of channel structures.

15. The semiconductor device of claim 10, further comprising a plurality of additional semiconductor layers respectively disposed on respective sides of the respective ones of the plurality of channel structures, wherein respective ones of the plurality of additional semiconductor layers are disposed on side surfaces of the first, second and third semiconductor layers.

16. The semiconductor device of claim 15, further comprising a plurality of source/drain regions respectively disposed on opposite sides of the nanosheet structure, wherein the plurality of additional semiconductor layers are disposed between the respective sides of the respective ones of the plurality of channel structures and one of the plurality of source/drain regions.

17. The semiconductor device of claim 15, wherein the plurality of additional semiconductor layers comprise the second semiconductor material.

18. A semiconductor device comprising:
a nanosheet transistor comprising a plurality of channel structures in a stacked configuration with a plurality of gate structures;
wherein each channel structure of the plurality of channel structures comprises a middle semiconductor layer disposed between two outer semiconductor layers; and
wherein the two outer semiconductor layers comprise a different semiconductor material than a semiconductor material of the middle semiconductor layer.

19. The semiconductor device of claim 18, wherein:
the two outer semiconductor layers comprise silicon germanium; and
the middle semiconductor layer comprises silicon.

20. The semiconductor device of claim 18, wherein:
the nanosheet transistor further comprises a plurality of spacers disposed on sides of the plurality of gate structures; and
end portions of the two outer semiconductor layers and of the middle semiconductor layer are disposed between two of the plurality of spacers.
